(19) United States
(12) Patent Application Publication
(10) Pub. No.: US 2018/0129141 A1
(43) Pub. Date: May 10, 2018

(54) TRANSFERRING APPARATUS

(71) Applicant: Samsung Electronics Co., Ltd., Suwon-si (KR)

(72) Inventors: Jong-In LEE, Seoul (KR); Sang-lk CHA, Cheonan-si (KR)

(73) Assignee: Samsung Electronics Co., Ltd., Suwon-si (KR)

(21) Appl. No.: 15/610,802

(22) Filed: Jun. 1, 2017

(30) Foreign Application Priority Data
Nov. 8, 2016 (KR) 10-2016-0148087

(51) Int. Cl. G03F 7/20

(52) U.S. Cl. CPC G03F 7/70733

(57) ABSTRACT

A transferring apparatus for transferring an object in a ceiling of a manufacturing line includes a travelling part configured to transfer the object along a desired travelling path provided in the ceiling, and an auxiliary support part configured to prevent the object from falling down while the traveling part travels. The auxiliary support part includes a linkage portion in a lower end portion of a frame which extends downwardly from the travelling part and including a horizontally spreadable link structure toward a bottom surface of the object, and a driving portion provided in the frame to provide a driving force for driving the linkage portion.

### PRIORITY STATEMENT

This application claims priority under 35 U.S.C. § 119 to Korean Patent Application No. 10-2016-0148087, filed on Nov. 8, 2016 in the Korean Intellectual Property Office (KIPO), the contents of which are herein incorporated by reference in their entirety.

### BACKGROUND

Example embodiments relate to a transferring apparatus. More particularly, example embodiments relate to a transferring apparatus such as an overhead hoist transfer in use of transferring an object such as a mask, photomask, plate, or reticle used during manufacturing of or fabrication of an integrated circuit device. The integrated circuit device may be a semiconductor device, a flat panel display, etc.

In manufacturing of an integrated circuit device such as a semiconductor device, a flat panel display, etc., a transferring process may be performed to transfer an object used in the manufacturing or fabrication of the integrated circuit device.

An overhead hoist transfer (OHT) may be used for the transferring apparatus in manufacturing or fabrication of the integrated circuit device. The OHT may be in a ceiling of a clean room in a manufacturing line or fabrication line used in the manufacturing or fabrication of the integrated circuit device.

In particular, the transferring apparatus may include a travelling part configured to transfer the object along a rail as a transferring path, a gripper configured to grip the object, a hoist configured to raise and lower the object, and an auxiliary support part configured to reduce the likelihood that an object falls down during traveling of the travelling part. The auxiliary support part may contact both side surfaces of the object.

Accordingly, particles may be generated in regions where the auxiliary support part and the object contact each other.

### SUMMARY

Example embodiments provide a transferring apparatus capable of minimizing or reducing occurrence of particles between an auxiliary support part and an object.

In one embodiment, a transferring apparatus includes a travelling part configured to transfer an object along a travelling path provided in a ceiling of a fabrication line, and an auxiliary support part configured to support the object while the traveling part travels. The auxiliary support part includes a linkage portion in a lower end portion of a frame, the linkage portion extending downward from the travelling part and including a horizontally spreadable link structure toward a bottom surface of the object and a driving portion provided in the frame configured to provide a driving force for driving the linkage portion.

In one embodiment, a transferring apparatus is configured to transfer a photomask along a traveling path includes an auxiliary support part configured to support the photomask as the traveling part travels. The auxiliary support part includes a linkage portion in a lower end portion of a frame, the linkage portion extending downward from the travelling part and including a horizontally spreadable link structure toward a bottom surface of the photomask.

In some example embodiments, the auxiliary support part further include a support portion protruding from the linkage portion to make contact with the object when the linkage portion is positioned under the object.

In some example embodiments, the auxiliary support part further includes a shock absorber between the linkage portion and the support portion.

According to some example embodiments, an auxiliary support part of a transferring apparatus may support a bottom surface of an object, not a side surface of the object. Because the auxiliary support part supports the bottom surface of the object, even though a plurality of protrusions of the support portion make point contacts with the object, the object may be supported securely, to reduce the likelihood that the object fails down.

Accordingly, the transferring apparatus may support and make point contacts with the bottom surface of the object, not the side surfaces of the object, and may make point contacts with the object. Thus, generation of particles between the auxiliary support part and the object may be minimized or reduced, to thereby improve process reliability, yield, and/or competitive strength of product.

### BRIEF DESCRIPTION OF THE DRAWINGS

Some example embodiments will be more clearly understood from the following detailed description taken in conjunction with the accompanying drawings. FIGS. 1 and 2 represent non-limiting, example embodiments as described herein.

FIGS. 1 and 2 are views illustrating a transferring apparatus in accordance with example embodiments.

### DETAILED DESCRIPTIONs

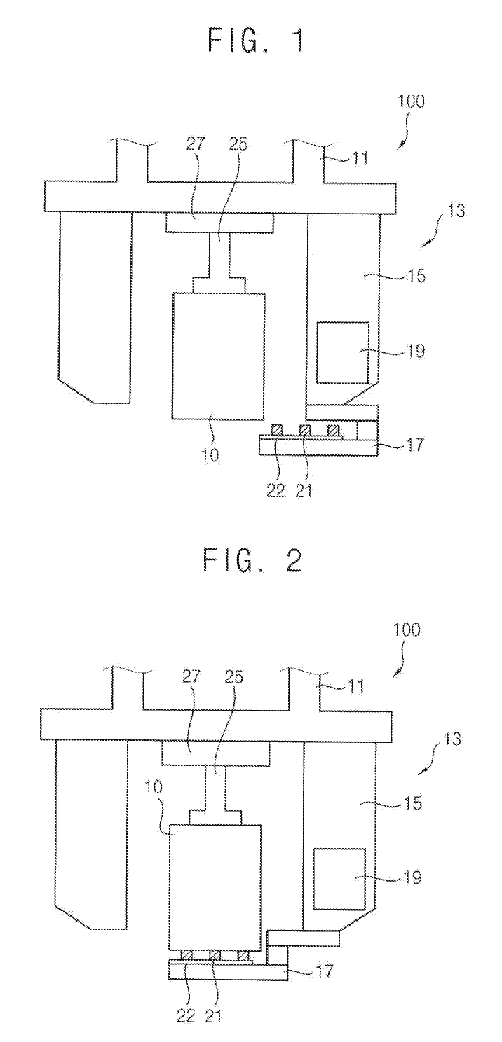

FIGS. 1 and 2 are views illustrating a transferring apparatus in accordance with example embodiments.

Referring to FIGS. 1 and 2, a transferring apparatus 100 in use of manufacturing an integrated circuit device may be an overhead hoist transfer (OHT), and may include a travelling part 11 configured to transfer an object 10 along a rail. The transferring apparatus 100 may include an auxiliary support part 13 configured to maintain a position of the object 10 during travelling and support the object 10 while the travelling part 11 travels.

The transferring apparatus 100 may further include a loading part 25 connected to the travelling part 11 and configured to grip and raise/lower the object 10, and an adjusting part 27 between the travelling part 11 and the loading part 25 and configured to adjust the position of the object 10 while the traveling part 11 travels.

The travelling part 11 may travel along the rail according to a desired, or alternatively predetermined travelling path, and may transfer the object 10. The travelling part 11 may include the rail installed in a ceiling of a manufacturing or fabrication line of the integrated circuit device. The traveling part 11 may include a plurality of wheels travelling along the rail, a body supporting the wheels, a driving motor for driving the wheels, and/or other components.

The loading part 25 may be connected to the travelling part 11 and grip and raise/lower the object 10. The loading part 25 may be mounted on a lower portion of the travelling part 11. The loading part may include a hand gripper for gripping the object 10, a hoist for raising/lowering the hand gripper, etc.

The adjusting part 27 may be between the travelling part 11 and the loading part 25 and may adjust the position of the object 10. The adjusting part 27 may include a slider, a rotator, etc., for moving the object 10 in a direction on a horizontal plane. For example, the slider may be mounted on a lower surface of the travelling part 11, and the rotator may be mounted on a lower surface of the slider.

The auxiliary support part 13 may be mounted on the travelling part 11, and may include a linkage portion 17, a driving portion 19, a support portion 21, etc. The linkage portion 17 and the driving portion 19 of the auxiliary support part 13 may be installed in a frame 15 which extends downwardly from the travelling part 11. Here, the frame 15 may be a body extending downwardly from the travelling part 11 by a predetermined, or alternatively desired distance, and the frame 15 may face both sides of the object 10.

The linkage portion 17 may be in a lower end portion of the frame 15. The linkage portion 17 may have a horizontally spreadable shape toward a bottom surface of the object 10. The linkage portion 17 may have a multi-joint structure, and may spread (move forth) by a rotation of an input link. When the linkage portion 17 spreads fully, the linkage portion 17 may cover the entire bottom surface of the object 10. The linkage portion 17 may include a mesh type of a frame.

The driving portion 19 may drive the linkage portion 17. The driving portion 19 may provide a driving force to the linkage portion 17 such that the multi-joint structure of the linkage portion 17 may rotate to spread and fold (e.g. to move forth and back). The driving portion 19 may include a ball screw, a linear motion (LM) guide, a drive belt, etc. The driving portion 19 may be provided in the frame 15. Accordingly, the driving portion 19 may be provided in the lower end portion of the frame 15 to be connected to the linkage portion 17.

The support potion 21 may be provided on the linkage portion 17 to support the object 10. The support portion 21 may include a plurality of protrusions protruding from the linkage portion 17. The protrusions of the support portion 21 may be arranged at intervals including regular intervals along an edge of the mesh type of the frame to be spaced apart from each other. When the support portion 21 is positioned under the object 10, the support portion 21 may make contact with the object 10 to support the object 10. The protrusions of the support portion 21 may make a point contact with the object 10.

The auxiliary support part 13 may further include a shock absorber 22 between the linkage portion 17 and the support portion 21. The shock absorber 22 may absorb a shock generated when the auxiliary support part 13 supports the object 10, to thereby minimize or reduce generation of particles.

As mentioned above, the transferring apparatus 100 may include the auxiliary support part 13 to support the bottom surface of the object 10. The auxiliary support part 13 may be provided in the transferring apparatus 100 to support the bottom surface of the object 10 in order to support the object 10 while the travelling part 11 travels. A plurality of the protrusions of the support portion 21 may make point contacts with the object 10, to more securely support the object 10.

Accordingly, the auxiliary support part may support and make point contacts with the bottom surface of the object, not the side surface of the object, to thereby minimize or reduce generation of particles. The transferring apparatus may be used in manufacturing or fabricating an integrated circuit device, to thereby improve process reliability, yield, and/or competitive strength of product.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims.

What is claimed is:

1. A transferring apparatus, comprising:
a travelling part configured to transfer an object along a travelling path provided in a ceiling of a manufacturing line; and
an auxiliary support part configured to support the object while the traveling part travels,
the auxiliary support part including,
a linkage portion in a lower end portion of a frame, the linkage portion extending downward from the travelling part and including a horizontally spreadable link structure toward a bottom surface of the object; and
a driving portion provided in the frame configured to provide a driving force for driving the linkage portion.

2. The transferring apparatus of claim 1, wherein the auxiliary support part includes,
a support portion protruding from the linkage portion and configured to make contact with the object when the linkage portion is positioned under the object.

3. The transferring apparatus of claim 2, wherein the auxiliary support part includes,
a shock absorber between the linkage portion and the support portion.

4. The transferring apparatus of claim 2, wherein the support portion includes,
a plurality of protrusions protruding from the linkage portion.

5. The transferring apparatus of claim 4, wherein the protrusions are arranged at regular intervals.

6. The transferring apparatus of claim 1, wherein the driving portion includes at least one of a ball screw, a linear guide, and a belt.

7. A transferring apparatus, comprising:
a traveling part configured to transfer a photomask along a traveling path provided in a ceiling of a fabrication line; and
an auxiliary support part configured to support the object as the traveling part travels,
the auxiliary support part including
a linkage portion in a lower end portion of a frame, the linkage portion extending downward from the travelling part and including a horizontally spreadable link structure toward a bottom surface of the photomask.

8. The transferring apparatus of claim 7, wherein the linkage portion includes, a multi-joint structure configured to spread by rotation of an input link.

9. The transferring apparatus of claim 7, wherein the linkage portion includes, a mesh type of frame.

10. The transferring apparatus of claim 7, further comprising:
a loading part on the transferring part, the loading part configured to grip the photomask.

11. The transferring apparatus of claim 10, further comprising:
an adjusting part between the traveling portion and the loading part, the adjusting part configured to adjust a position of the photomask.
